(19) United States
(12) Patent Application Publication
(10) Pub. No.: US 2026/0163542 A1
(43) Pub. Date: Jun. 11, 2026

(54) VARIABLE GAIN AMPLIFICATION AND PHASE SHIFTING DEVICE AND METHOD

(71) Applicant: STMicroelectronics International N.V., Geneva (CH)

(72) Inventors: Leonardo Gomes, Grenoble (FR); Frederic Paillardet, Tresserve (FR)

(21) Appl. No.: 19/412,659

(22) Filed: Dec. 8, 2025

(30) Foreign Application Priority Data
Dec. 9, 2024 (EP) 24315561.1
Jun. 27, 2025 (EP) 25315230.0

(51) Int. Cl. H03G 3/30

(52) U.S. Cl. CPC H03G 3/30; H03G 2201/103

(57) ABSTRACT

The present description concerns a variable-gain amplification device and a variable-gain amplification method, in which a segmentation of a current switching is implemented in at least two parts.

### CROSS-REFERENCE TO RELATED APPLICATIONS

This application claims the priority benefit of European Patent Application No. 24315561.1, filed on Dec. 9, 2024, and of European Patent Application No. 25315230.0, filed on Jun. 27, 2025, all of which applications are hereby incorporated herein by reference.

### TECHNICAL FIELD

The present disclosure generally concerns electronic circuits and methods, and more particularly, variable-gain amplifier circuits, also known as variable gain amplifiers (VGA), and associated methods.

### BACKGROUND

Variable gain amplifier circuits intended to amplify radio frequency signals with a controlled gain are used in many radio frequency circuits, for example in radio frequency circuits provided to operate in the millimeter wave (mmW) range, in the Ku (“Kurz-under”) or Ka (“Kurz-above”) bands, in the 4G, 5G, 6G bands, and in other radio frequency bands.

Phase shifters enabling application of a controllable phase shift ranging from 0° to 360° to a radio frequency signal are, for example, used in the field of beamforming. Beamforming is implemented in many applications, for example in the field of LEO or GEO satellite communications, or in the field of 5G or 6G.

RTPS (Reflection Type Phase Shifters) phase shifters are well-known passive phase shifters. However, a disadvantage of these known phase shifters is that they are bulky and that they are configured to operate at a target frequency, and thus do not have a stable response when the signals to be phase-shifted belong to a frequency band.

Another type of known phase shifters is based on a generator (or modulator) of signals in phase and in quadrature I/Q, and two variable-gain amplifiers for enabling a controlled amplification of each of the I and Q signals.

Although these phase shifters based on variable-gain amplifications do not suffer from the disadvantages indicated hereabove for RTPS phase shifters, these phase shifters based on variable-gain amplifications have other disadvantages, some of these disadvantages directly resulting from disadvantages of the known variable-gain amplifiers used in these phase shifters.

### SUMMARY

There exists a need to overcome all or part of the disadvantages of known variable-gain amplifier circuits.

An embodiment overcomes all or part of the disadvantages of known variable-gain amplifier circuits.

An embodiment provides a variable-gain amplifier device configured to implement a segmentation of a current switching into at least two parts.

Another embodiment provides a variable-gain amplification method in which a current switching in a variable-gain amplification device is segmented into at least two parts.

According to an embodiment, the device implements a segmentation of a transconductance gain into at least two parts.

According to an embodiment:
the device comprises a Gilbert cell, the Gilbert cell comprises a transconductance stage, a current switching stage, and a load stage, the current switching stage is connected between the transconductance stage and the load stage, and the segmentation of the current switching into at least two parts is implemented in the current switching stage.

According to an embodiment:
the device is configured to receive a control signal over N bits, with N a positive integer greater than or equal to 4,
a first one of the at least two parts of the segmentation of the current switching is configured to be controlled by n1 bits of the control signal, and
a second one of the at least two parts of the segmentation of the current switching is configured to be controlled by n2 bits of the control signal, with n1 and n2 non-zero positive integers and N=n1+n2.

According to an embodiment, the current switching is at least partly implemented by bipolar transistors, preferably BiMOS transistors.

According to an embodiment:
the device comprises a Gilbert cell, the Gilbert cell comprises a transconductance stage, a current switching stage, and a load stage, the current switching stage is connected between the transconductance stage and the load stage, the segmentation of the current switching into at least two parts is implemented in the current switching stage, and
the segmentation of the transconductance gain into at least two parts is implemented in the transconductance stage.

According to an embodiment:
the device is configured to receive a control signal over N bits, with N a positive integer greater than or equal to 4
a first one of the at least two parts of the segmentation of the current switching is configured to be controlled by n1 bits of the control signal,
a second one of the at least two parts of the segmentation of the current switching is configured to be controlled by n2 bits of the control signal,
with n1 and n2 non-zero positive integers and N=n1+n2,
a first one of the at least two parts of the segmentation of the transconductance gain is configured to implement a transconductance gain equal to gm1, and
a second one of the at least two parts of the segmentation of the transconductance gain is configured to implement a transconductance gain equal to gm1/(2^{N-n2}).

According to an embodiment, the current switching is at least partly implemented by bipolar transistors, preferably BiMOS transistors, and the transconductance gain is at least partly implemented by bipolar transistors, preferably BiMOS transistors.

According to an embodiment, at least one of the at least two parts of the current switching segmentation is implemented continuously.

According to an embodiment, at least one of the at least two parts of the continuously-implemented current switching segmentation comprises a digital-to-analog converter.

According to an embodiment, at least one of the at least two parts of the current switching segmentation is implemented discretely.

Another embodiment provides a phase shifting device comprising at least one device such as defined hereabove.

According to an embodiment, the phase shifting device comprises:
a first device such as defined hereabove, configured to apply a first gain to a first signal; and
a second device such as defined hereabove, configured to apply a second gain to a second signal in quadrature with the first signal, the first and second gains determining a phase-shift value, and the phase shifting device comprising, for example, an I/Q modulator configured to supply the first and second signals.

Another embodiment provides a device for emitting or receiving a shaped beam, comprising a plurality of phase shifting devices such as defined hereabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows in the form of blocks an embodiment of a variable-gain amplifier;

FIG. 2 illustrates, with a circuit, the operation of a circuit of the amplifier of FIG. 1;

FIG. 3 shows an example of an embodiment of a circuit of the amplifier of FIG. 1;

FIG. 4 shows an example of an embodiment of another circuit of the amplifier of FIG. 1;

FIG. 5 shows an example of another embodiment of the circuit of FIG. 4;

FIG. 6 shows an example of another embodiment of a variable-gain amplifier;

FIG. 7 shows an example of an embodiment of a phase shifter comprising two variable-gain amplifiers;

FIG. 8 shows an example of an embodiment of a circuit for emitting a shaped beam; and

FIG. 9 shows an example of an embodiment of a circuit for receiving a shaped beam.

### DETAILED DESCRIPTION OF ILLUSTRATIVE EMBODIMENTS

The same elements have been designated by the same references in the various figures. The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

There is here provided a variable-gain amplifier in which a segmentation, or separation into at least two parts, of a current switching is implemented.

As will be described in more detail hereafter, when the different parts of the current segmentation are each implemented discretely, there is also provided a segmentation, or separation into at least two parts, of a transconductance gain. Preferably, in this case, the number of parts of the current segmentation is equal to the number of parts of the gain segmentation.

As will be described in more detail hereafter, when the different parts of the current segmentation are each implemented continuously, there is also provided a segmentation, or separation into at least two parts, of a transconductance gain. Preferably, in this case, the number of parts of the current segmentation is equal to the number of parts of the gain segmentation.

As will be described in more detail hereafter, when one or more parts of the current segmentation are each implemented discretely, and one or more other parts of the current segmentation are each implemented continuously, it may be provided either to segment the transconductance gain, or for the transconductance gain segmentation to be omitted.

In practice, segmenting the current switching amounts to segmenting the control of the variable gain of the amplifier.

Further, the variable-gain amplifier provided herein comprises a cell (or mixer) of the Gilbert type. The cell comprises a transconductance stage, a current switching stage in which a segmentation of the current switching is implemented, and a load stage. The current switching stage is segmented into a plurality of parts and is connected between the transconductance stage and the load stage. Preferably, when the transconductance gain is also segmented, each part of the current segmentation is connected between a corresponding part of the gain segmentation and the load stage. When the transconductance gain is segmented, this segmentation is implemented in the transconductance stage. As an example, in usual fashion, the Gilbert cell comprises a circuit for biasing the transconductance stage.

The provision of a current switching segmentation in a variable-gain amplifier enables decreasing the number of components used in the RF path, and thus decreasing the output capacitance of the variable-gain amplifier, or, in other words, increasing the output impedance of the amplifier. This increase in the output impedance is achieved without decreasing the gain and the accuracy of the gain control.

As an example, the increase in the output impedance of the amplifier is advantageous in bidirectional radio frequency (RF) front-end circuits, since it enables avoiding the gain drop resulting from the low impedances of known variable-gain amplifiers.

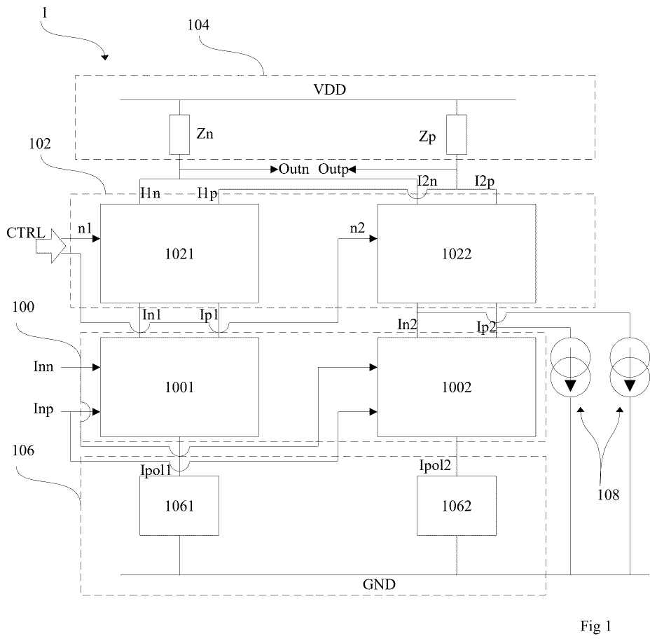

FIG. 1 schematically shows in the form of blocks an embodiment of a variable-gain amplifier 1, in which a segmentation of the current switching into M parts 102j is implemented, where j is an integer ranging from 1 to M, and M is a positive integer greater than or equal to 2. Amplifier 1 enables implementing a variable-gain amplification in which the current switching performed in amplifier 1 is segmented into M parts.

In the example of FIG. 1, M is equal to 2 and the current switching is segmented into two parts 1021 and 1022.

Further, in the embodiment of FIG. 1, the transconductance gain is also segmented into a plurality of parts. More particularly, in the example of FIG. 1, the transconductance gain is also segmented into M parts 100j (1001 and 1002 in FIG. 1).

Variable-gain amplifier device 1 comprises a Gilbert cell comprising a transconductance stage 100, a current switching stage 102, and a load stage 104. The current switching stage 102 is connected between transconductance stage 100 and load stage 104. Further, as is usual in a Gilbert cell, amplifier 1 comprises a circuit 106 for biasing transconductance stage 100.

Transconductance stage 100 is configured to receive the two components Inp and Inn of a differential signal (voltage) to be amplified. Stage 100 is configured to supply, to each part 102j of the current switching segmentation implemented at stage 102, two currents resulting from a product of a transconductance value by, respectively, the two components Inp and Inn of the signal to be amplified.

In this embodiment, where the transconductance gain is segmented into M parts 100j, each part 100j receives the two components Inn and Inp of the differential signal to be amplified. Further, each part 100j is configured to supply two currents Inj and Ipj resulting from a product of a transconductance value and, respectively, of the two components Inp and Inn of the signal to be amplified. Preferably, transconductance value gmj is different for each part 100j of the transconductance gain segmentation.

In the example of FIG. 1, part 1001 delivers a current In1 resulting from the product of a transconductance gm1 and of component Inn, and a current Ip1 resulting from the product of transconductance gm1 and of component Inp. Further, in the example of FIG. 1, part 1002 delivers a current In2 resulting from the product of a transconductance gm2 and of component Inn, and a current Ip2 resulting from the product of transconductance gm2 and of component Inp.

In the example of FIG. 1, preferably, transconductance gm2 is equal to gm1/(2^{N-n1}), that is, to gm1/2ⁿ².

Preferably, on the outputs of each part 100j of the transconductance gain segmentation which does not correspond to the highest transconductance value gmj, a DC compensation circuit is provided. For each part 100j of the transconductance segmentation which does not correspond to the highest transconductance value, the DC compensation aims, for example, at adding two DC currents to the two currents Inj and Ipj delivered by this part 100j of the segmentation, so as to compensate for the difference between the common-mode amplification by this part of the transconductance segmentation and the common-mode amplification of the part of the current segmentation corresponding to the highest transconductance value gmj.

For example, in the example of the drawing, it is considered that gm2 is lower than gm1, and a DC compensation circuit 108 is provided on the outputs of part 1002 of stage 100.

Biasing stage 106 is configured to bias stage 100, that is, to supply at least one current for biasing transconductance stage 100. In the example of FIG. 1, stage 106 is configured to supply a bias current Ipolj (Ipol1 and Ipol2 in FIG. 1) to each part 100j of stage 100.

For example, stage 106 comprises a single current source supplying a bias current Ipol distributed in the form of currents Ipolj between the parts 100j of stage 100. As another example, as shown in FIG. 1, stage 106 comprises as many current sources 106j as there are parts 100j in transconductance stage 100. For example, in FIG. 1, stage 106 comprises a current source 1061 configured to supply bias current Ipol1 to part 1001 of stage 100, and a current source 1062 configured to supply bias current Ipol2 to part 1002 of stage 100.

Stage 106 is connected between stage 100 and a first power supply potential, for example, a low power supply potential, or reference potential, for example ground GND.

As an example, each current source 106j of stage 106 is connected between stage 100 and potential GND, for example between a corresponding part 100j of stage 100 and potential GND.

As an example, when the transconductance gain is segmented, as is the case in the embodiment illustrated in FIG. 1, and stage 100 comprises a plurality of parts 100j each having a different transconductance value gmj, the transconductance value gmj of this part 100i of stage 100 can be determined by the dimensions of the transistors used to implement this part 100j of stage 100, and/or by the value of the bias current Ipolj received from stage 106 by this part 100j of stage 100.

Each part 102j of the current switching segmentation, or, in other words, each part 102j of stage 102, is configured to receive a corresponding part of the N bits of a control signal CTRL received by stage 102, with N a positive integer greater than or equal to 2, for example greater than or equal to 4. In other words, each part 102i is configured to receive nj bits from the N bits, preferably nj bits having successive significances and being different from the nj bits received by each other part 102j of stage 100. The sum of the nj bits received by parts 102j is equal to N.

For example, in FIG. 1, part 1021 receives n1 bits from among the N bits of signal CTRL, and part 1022 receives n2 other bits from among the N bits of signal CTRL, where N=n1+n2. n1 and n2 each are positive integers.

Each part 102j of stage 102 is configured to divide the current Inj that it receives into two portions, the first portion of current Inj being supplied to an output Outn of device 1, the second portion of this current Inj being supplied to an output Outp of device 1. The ratio of the first and second portions of current Inj is determined by the state nj of the control bits. Symmetrically, each part 102j of stage 102 is configured to divide the current Ipj that it receives into two portions, the first portion of this current Ipj being delivered to the output Outn of device 1, the second portion of this current Ipj being delivered to the output Outp of device 1. The ratio of the first and second portions of current Ipj is determined by the state of the nj control bits. The sum of the first portions of currents Inj and Inpj delivered to the output Outn of the device is designated with reference Ijn, and the sum of the first portions of currents Inj and Inpj which is supplied to the output Outn of the device is designated with reference Ijp.

As an example, in FIG. 1, part 1021 of stage 102 supplies output Outn with a current I1n corresponding to the sum of the first portion of current In1 and of the first portion of current Ip1, and supplies output Outp with a current I1p corresponding to the sum of the second portion of current In1 and of the second portion of current Ip1. The values of currents I1n and I1p are determined by currents In1 and Ip1 and by the n1 control bits received by part 1021. Similarly, in FIG. 1, part 1022 of stage 102 supplies output Outn with a current I2n corresponding to the sum of the first portion of current In2 and of the first portion of current Ip2, and supplies output Outp with a current I2p corresponding to the sum of the second portion of current In2 and of the second portion of current Ip2. The values of currents I2n and I2p are determined by currents In2 and Ip2 and by the n2 control bits received by part 1022.

Load stage 104 is connected between outputs Outn and Outp, and a power supply potential, for example a high power supply potential VDD. In other words, stage 104 is connected between stage 102 and potential VDD.

Stage 104 is configured to convert the sum of the currents Ijn (I1n and I2n in FIG. 1) supplied to output Outn by stage 102 into a voltage available at output Outn, and the sum of the currents Ijp (Isp and I2p in FIG. 1) supplied to output Outp by stage 102 into a voltage available at output Outp. For example, load stage 104 comprises an impedance Zn connected between output Outn and potential VDD, and an impedance Zp connected between output Outp and potential VDD, impedance Zp being identical to impedance Zn.

The voltages available on the two outputs Outn and Outp of device 1 correspond to the two components of a differential output signal of device 1, this output voltage corresponding to the differential input voltage Inn, Inp amplified by a gain having its value controlled by the N bits of signal CTRL.

Preferably, in the embodiment of FIG. 1 where the transconductance gain is segmented, the significance of the nj bits controlling each part 102j of stage 102 increases with the transconductance value gmj of the part 100j of stage 100 supplying the two currents Inj and Ipj to this part 102j of stage 102.

In the example of FIG. 1 where part 1021 receives currents In1 and Ip1 from the part 1001 corresponding to a transconductance of value gm1, and part 1022 receives currents In2 and Ip2 from the part 1002 corresponding to a transconductance of value gm2 lower than value gm1, the n1 bits of signal CTRL are more significant than the n2 bits of signal CTRL, or, in other words, the n1 bits are the more significant bits of signal CTRL and the n2 bits are the least significant bits of signal CTRL.

Preferably, in device 1, the current switching operations controlled by signal CTRL are implemented by bipolar transistors, which allow higher gains for an equivalent surface area than MOS transistors, although an implementation with MOS transistors can be envisaged. Moreover, when current switching operations are implemented by bipolar transistors, the latter are preferably BiCMOS transistors, which have lower noise than conventional bipolar transistors.

Similarly, the transconductance stage is preferably implemented by bipolar transistors, which allow higher gains for an equivalent surface area than MOS transistors, although an implementation with MOS transistors can be envisaged. When the transconductance stage is implemented by bipolar transistors, the latter are preferably BiCMOS transistors, which have lower noise than conventional bipolar transistors.

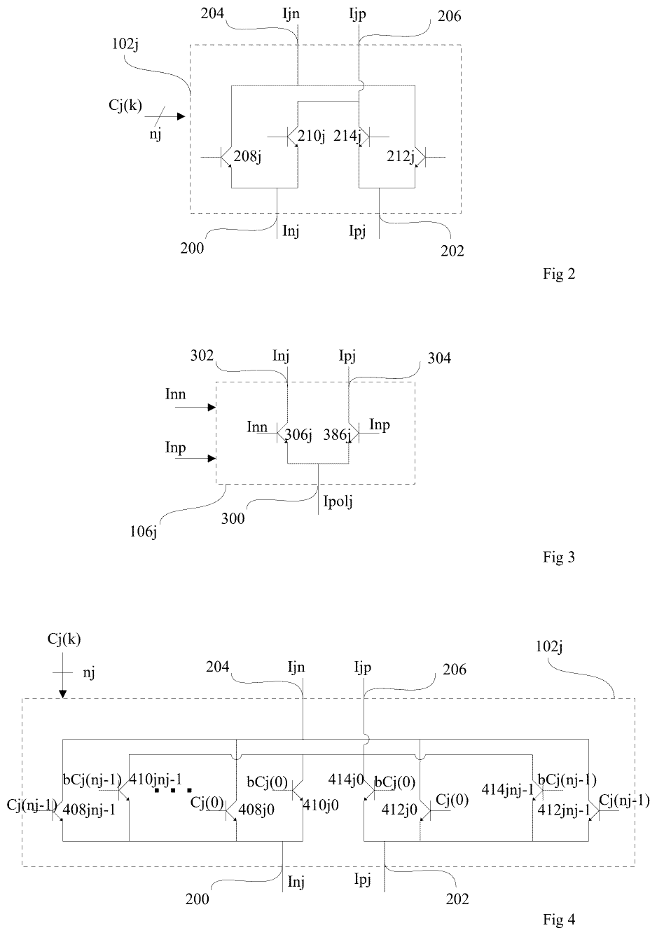

FIG. 2 illustrates, by means of a circuit, the operation of a circuit corresponding to part 102j of the current segmentation of the amplifier 1 of FIG. 1.

Part 102j comprises an input 200 configured to receive current Inj, and an input 202 configured to receive current Ipj. Part 102j comprises an output 204 configured to deliver current Ijn and an output configured to deliver current Ijp.

Part 102j receives nj control bits Cj(k), where k is an integer ranging from 0 to nj-1.

The nj bits Cj(k) control one or more transistors connected in parallel between input 200 and output 204, these transistors being represented by a single transistor 208j in FIG. 2, and one or more transistors connected in parallel between input 200 and output 206, these transistors being represented by a single transistor 210j in FIG. 2.

Transistors 208j and 210j form a first differential pair controlled by nj bits Cj(k). Transistors 208j and 210j are controlled in complementary fashion. For example, transistor 208j is controlled by bits Cj(k), and transistor 210j is controlled by bits bCj(k), each bit bCj(k) being the binary complement of the bit Cj(k) of same index k.

Symmetrically, the nj bits Cj(k) control one or more transistors connected in parallel between input 202 and output 204, these transistors being represented by a single transistor 212j in FIG. 2, and one or more transistors connected in parallel between input 202 and output 206, these transistors being represented by a single transistor 214j in FIG. 2.

Transistors 212j and 214j form a second differential pair controlled by nj bits Cj(k). Transistors 212j and 214j are controlled in complementary fashion. For example, transistor 212j is controlled, in the same way as transistor 208j, by bits Cj(k), and transistor 214j is controlled, in the same way as transistor 210j, by bits bCj(k).

Thus, depending on the state of the nj control bits, a percentage X of current Inj is transmitted to output 204, a percentage 100-X of current Inj is transmitted to output 206, a percentage X of current Ipj is transmitted to output 204, and a percentage 100-X of the Ipj current is transmitted to output 206.

It will be seen hereafter that each of the transistors 208j, 210j, 212j, and 214j may be implemented by a single transistor controlled by a continuous signal determined by the nj bits Cj(k) (continuous implementation of part 102j), or by a plurality of transistors in parallel controlled by the nj bits Cj(k), for example nj transistors in parallel, each controlled by a bit Cj(k) of different index (discrete implementation).

FIG. 3 illustrates an example of an embodiment of a circuit of the amplifier of FIG. 1 corresponding to a part 100j of the transconductance segmentation of the amplifier 1 of FIG. 1.

Part 100j comprises an input 300 configured to receive current Ipolj, an output 302 configured to deliver current Inj, and an output 304 configured to deliver current Ipj.

A transistor 306j is connected between input 300 and output 302, and a transistor 308j is connected between input 300 and output 304.

Transistors 306j and 308j form a differential pair controlled by the components Inp and Inn of the input signal. Transistors 306j and 308j are controlled in complementary fashion. For example, transistor 306j is controlled by the component Inn of the input signal, and transistor 308j is controlled by the component Inp of the input signal.

FIG. 4 shows an example of an embodiment of a circuit corresponding to a part 102j of the current segmentation of the amplifier 1 of FIG. 1.

More specifically, in this embodiment, the current switching operations in circuit 102j are implemented discretely.

The transistor 208j of FIG. 2 corresponds, in this embodiment, to nj transistors 408jk in parallel between the input 200 of circuit 102j and the output 204 of circuit 102j, with k an index ranging from 0 to nj-1. Each transistor 408jk is controlled by the corresponding bit Cj(k) of index k, the significance of the nj bits Cj(k) increasing with index k. Further, each transistor 408jk has, for example, dimensions 2 times larger than the transistor 408jk-1 of index k-1. For example, transistor 408j1 is twice as large as transistor 408j0.

Similarly, the transistor 210j shown in FIG. 2 corresponds, in this embodiment, to nj transistors 410jk in parallel between input 200 of circuit 102j and output 206 of circuit 102j. Each transistor 410jk is controlled by the binary complement bCj(k) of the corresponding bit Cj(k) of index k. Further, each transistor 410jk has, for example, dimensions 2 times larger than transistor 410jk-1 of index k-1, and, preferably, the same dimensions as the transistor 408jk of same index k.

The transistor 212j shown in FIG. 2 corresponds, in this embodiment, to nj transistors 412jk in parallel between input 202 of circuit 102j and output 204 of circuit 102j, with k an index ranging from 0 to nj-1. Each transistor 412jk is controlled by the corresponding bit Cj(k) of index k. Further, each transistor 412jk has, for example, dimensions 2 times larger than the transistor 412jk-1 of index k-1, and, preferably, the same dimensions as the transistor 408jk of same index k.

Similarly, the transistor 214j shown in FIG. 2 corresponds, in this embodiment, to nj transistors 414jk in parallel between input 202 of circuit 102j and output 206 of circuit 102j. Each transistor 414jk is controlled by the binary complement bCj(k) of the corresponding bit Cj(k) of index k. Further, each transistor 414jk has, for example, dimensions 2 times larger than the transistor 414jk-1 of index k-1, and the same dimensions as the transistor 408jk of same index k.

In FIG. 4, to avoid overloading the drawing, only transistors 408j0, 408jnj-1, 410j0, 410jnj-1, 412j0, 412jnj-1, 414j0, 414jnj-1, and bits Cj(0), Cj(nj-1), bCj(0), and bCj(nj-1) are shown.

As an example, each of transistors 408jk, 410jk, 412jk, and 414jk is implemented by one or more bipolar transistors, preferably one or more bipolar metal-oxide-semiconductor (BiMOS) transistors.

According to an embodiment, when a plurality of parts of the current segmentation are each implemented discretely by a corresponding circuit 102j such as described in relation with FIG. 4, in all these circuits 102j, transistors 408j0 all have the same dimensions. Returning to the example of FIG. 1, if each of circuits 1021 and 1022 is implemented discretely as shown in FIG. 4, then transistor 40810 has the same dimensions as transistor 40820. Further, preferably, as indicated hereabove as an example, transistors 40810, 40820, 41010, 41020, 41210, 41220, 41410, and 41420 all have the same dimensions.

FIG. 5 shows an example of an embodiment of a circuit corresponding to a part 102j of the current segmentation of the amplifier 1 of FIG. 1.

More particularly, in this embodiment, the current switching operations in circuit 102j are implemented continuously.

The transistor 208j shown in FIG. 2 corresponds, in this embodiment, to a transistor 508j connected between input 200 of circuit 102j and output 204 of circuit 102j. Transistor 508j is controlled by an analog signal determined by the nj bits Cj(k).

Similarly, the transistor 210j shown in FIG. 2 corresponds, in this embodiment, to a transistor 510j connected between input 200 of circuit 102j and output 206 of circuit 102j. Transistor 510j is controlled by an analog signal determined by the nj bits bCj(k) corresponding to the binary complements of the nj bits Cj(k). Transistor 510j has, for example, the same dimensions as transistor 508j.

The transistor 212j shown in FIG. 2 corresponds, in this embodiment, to a transistor 512j connected between input 202 of circuit 102j and output 204 of circuit 102j. Transistor 512j is controlled by an analog signal determined by the nj bits Cj(k). Transistor 512j has, for example, the same dimensions as transistor 508j.

Similarly, the transistor 214j shown in FIG. 2 corresponds, in this embodiment, to a transistor 514j connected between input 202 of circuit 102j and output 206 of circuit 102j. Transistor 514jk is controlled by an analog signal determined by the nj bits bCj(k) corresponding to the binary complements of the nj bits Cj(k). Transistor 514j has, for example, the same dimensions as transistor 508j.

In this embodiment, circuit 102j further comprises a digital-to-analog converter 500.

Converter 500 is configured to receive the nj bits Cj(k) and to convert them into an analog signal sigj.

Circuit 102j further comprises, in this example where transistors 508j, 510j, 512j, and 514j are bipolar transistors, for example BiMOS transistors, a linear-to-logarithmic conversion circuit 502 configured to receive signal sigi and to deliver two complementary signals siglogj and nsiglogj.

Transistors 208j and 212j are controlled by signal siglogj and transistors 510j and 514j are controlled by signal nsiglogj.

Although a circuit comprising the two circuits 500 and 502, configured to receive the nj bits Cj(k) and to deliver the analog control signals of transistors 508j, 510j, 512j and 514j in the case where there is a single converter 500, has been described, this circuit may comprise two converters 500, for example one converter 500 delivering signal sigj and another converter 500 delivering a signal nsigj complementary to signal sigj, this signal nsigj corresponding to the digital-to-analog conversion of the nj bits bCj(k).

Preferably, transistors 508j, 510j, 512j, and 514j all have the same dimensions.

As an example, each of transistors 508j, 510j, 512j, and 514j is implemented by one or more bipolar transistors, preferably one or more BiMOS transistors.

According to an embodiment, when a plurality of parts of the current segmentation are each implemented continuously by a corresponding circuit 102j as described in relation with FIG. 5, in all these circuits 102j, the transistors 508j of each two different stages 102j have dimensions configured to keep the same current density in these two stages 102j. For example, for each of the two stages 102j, the ratio of the dimensions of the transistor 508j of a first one of the two stages 102j to the dimensions of the transistors 508j of the second one of the two stages 102j follows the binary ratio of the nj control bits of the first one of the two stages 102j to the nj control bits of the second one of the two stages 102j. For example, taking the example of FIG. 1, in the case where each of circuits 1021 and 1022 is implemented continuously as shown in FIG. 5, then the ratio of the dimensions of transistor 5080 to the dimensions of transistor 5081 follows the binary ratio of the n1 control bits of stage 1021 to the n2 control bits of stage 1022. Further, preferably, as indicated hereabove as an example, the transistors 5081, 5101, 5121, and 5141 of stage 1021 all have the same dimensions, and the transistors 5082, 5102, 5122, and 5142 of stage 1022 all have the same dimensions.

According to an embodiment, all the parts 102j of the current segmentation, for example the two parts 1021 and 1022 of the example in FIG. 1, are implemented continuously, each by a circuit 102j as described in relation with FIG. 5.

According to an embodiment, when at least part of the current segmentation is implemented discretely, and at least another part of the current segmentation is implemented continuously, then the transistor 508j of each continuously implemented circuit 102j (FIG. 5) has dimensions determined by the binary ratio of its current step to the smallest current step of circuits 102j. In other words, between a continuously-implemented first stage 102j and a discretely-implemented second stage 102j, the ratio of the dimensions of the transistor 408jk of the discretely-implemented first stage 102j to the dimensions of the transistor 508j of the continuously-implemented second stage 102j is, for example, determined by the binary ratio of the control bit Cj(k) of the transistor 408jk of the discrete first stage 102j to the nj control bits Cj(k) of the transistor 408j of the continuous second stage 102j.

As an example, referring again to FIG. 1, signal CTRL encodes a discrete digital value Val in the range from 0 to 2N-1, and thus the value is determined by the state of the N bits of signal CTRL comprising n1 most significant bits and n2 least significant bits.

In this example, the gain, or transconductance, gm of device 1 is equal to the sum of the gains, or transconductances, gmeq1 and gmeq2, where gmeq1 is the equivalent gain, or transconductance, of the two circuits 1001 and 1021, and gmeq2 is the equivalent gain, or transconductance, of the two circuits 1002 and 1022. One then has the following equations:

$$gmeq 2 = gm 2. \frac{( {2}^{n 2} - 1 ) - 2 * ( val . mod ( {2}^{n 2} ) )}{( {2}^{n 2} - 1 )} \qquad [ Math 1 ]$$

where mod ( ) is the modulo operator, and:

$$gmeq 1 = gm 1. \frac{( {2}^{n 2} - 1 ) - 2 * ( val / {2}^{n 1} )}{( {2}^{n 2} - 1 )} \qquad [ Math 2 ]$$

Still in this example, the variation of transconductance gm1, noted Agm1, and the variation of transconductance gm2, noted Agm2, are then linked by the following equations:

$$Δ gm 1 = {2}^{n 2} . Δ gm 2 \qquad [ Math 3 ]$$

$$gm 2 = gm 1 / l \qquad [ Math 4 ]$$

with 1 a non-zero integer, and

$$Δ gm 2 = \frac{gm 1}{l} . \frac{2}{{2}^{n 2} - 1} \qquad [ Math 5 ]$$

As an example, to have a smooth transition, one then has:

$$Δ gm 1 = {2}^{n 2} . \frac{gm 1}{l} . \frac{2}{{2}^{n 2} - 1} = gm 1. \frac{2}{{2}^{n 1} - 1} \qquad [ Math 6 ]$$

Whereby:

$$l = {2}^{n 2} . \frac{{2}^{n 1} - 1}{{2}^{n 2} - 1} = {2}^{n 2} . \frac{{2}^{N - n 2} - 1}{{2}^{n 2} - 1} \qquad [ Math 7 ]$$

It can be understood that 1 is an integer if n1=n2=N/2, N being even.

However, in a general case, n2 may be different from N/2, or N may be odd. In this case, spare switches, that is, spare transistors, may be provided in one of circuits 102j, preferably in circuit 1022, so that 1 is an integer. Adding these spare transistors to circuit 1022 amount to adding:
a transistor 4082S identical to transistor 40820, transistor 4082S being connected between input 200 and the potential VDD to which load stage 104 is connected, and not between input 200 and output 204 as is the case for transistor 40820. Further, transistor 4082S is controlled in the same way as transistor 40820;
a transistor 4102S identical to transistor 41020, transistor 4102S being connected between input 200 and the potential VDD to which load stage 104 is connected, and not between input 200 and output 206 as is the case with transistor 41020. Further, transistor 4102S is controlled in the same way as transistor 41020;
a transistor 4122S identical to transistor 41220, transistor 4122S being connected between input 202 and the potential VDD to which load stage 104 is connected, and not between input 202 and output 204 as is the case for transistor 41220. Further, transistor 4122S is controlled in the same way as transistor 41220; and
a transistor 4142S identical to transistor 41420, transistor 4122S being connected between input 200 and potential VDD to which load stage 104 is connected, and not between input 202 and output 206 as is the case for transistor 41420. Further, transistor 4142S is controlled in the same way as transistor 41420.

Thereby, equation [Math7] becomes:

$$l = {2}^{n 2} . \frac{{2}^{n 1} - 1}{{2}^{n 2} - 1 + 1} = {2}^{n 1} - 1 = {2}^{N - n 2} - 1 \qquad [ Math 8 ]$$

As an example, if N is equal to 6 and n2 is equal to 3, by using equation [Math 7] corresponding to the case without spare switches, one obtains 1=8, and by using equation [Math 8] corresponding to the case with spare switches, one obtains 1=7.

As another example, if N is equal to 6 and n2 is equal to 4, by using equation [Math 7] corresponding to the case without spare switches, one obtains 1=16/5, which is not an integer, and by using equation [Math 8] corresponding to the case with spare switches, one obtains 1=3.

As another example, if N is equal to 7 and n2 is equal to 3, by using equation [Math 8] corresponding to the case with spare switches, one obtains 1=15.

In relation with FIG. 1, an embodiment of a variable-gain amplifier 1 has been described in which, not only is the current switching segmented into a plurality of parts (or circuits) 102j, but also is the transconductance gain segmented, for example, into as many parts (or circuits) 100j as there are circuits 102j.

In other embodiments, the current gain may not be segmented, in particular when amplifier 1 comprises only two parts 1021 and 1022 where one of parts 1021 and 1022 is implemented discretely, and the other of parts 1021 and 1022 is implemented continuously.

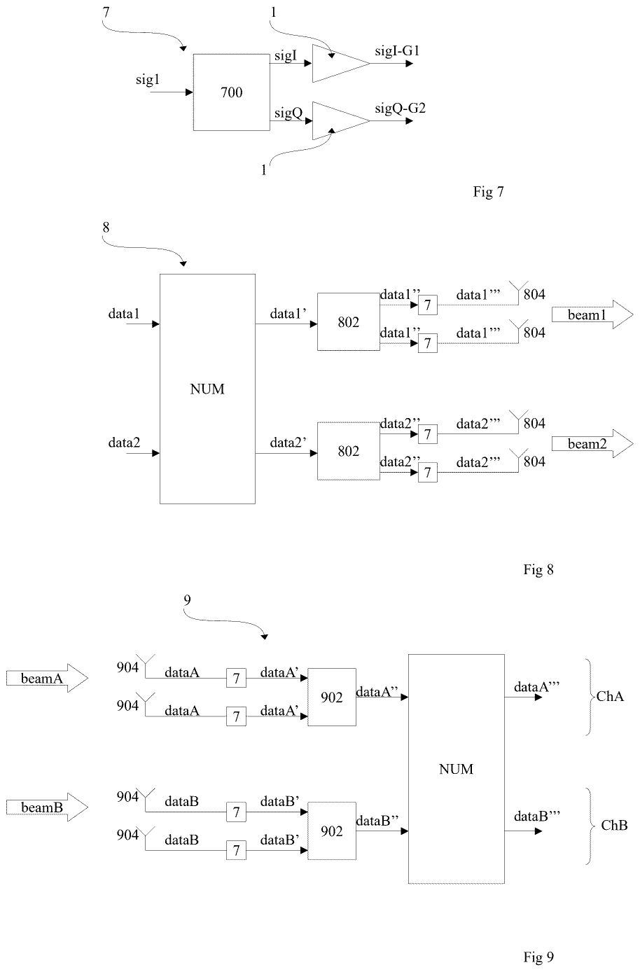

FIG. 7 shows, schematically and in the form of blocks, an embodiment of the variable-gain amplifier 1 in which the current switching is segmented, but the transconductance gain is not segmented. In this embodiment where the transconductance gain is not segmented, at least one of parts 102j is implemented discretely, while at least another of the parts is implemented continuously. More particularly, in the example of FIG. 7, current switching stage 102 is segmented into M equals 2 parts 1021 and 1022. Part 1021, respectively 1022, is, as an example, implemented discretely, respectively continuously.

The amplifier 1 of FIG. 7 has many elements in common with the amplifier 1 of FIG. 1, and only the differences between these two amplifiers 1 are detailed herein. Thus, unless otherwise indicated, what has been indicated for the amplifier of FIG. 1 applies to the amplifier of FIG. 7.

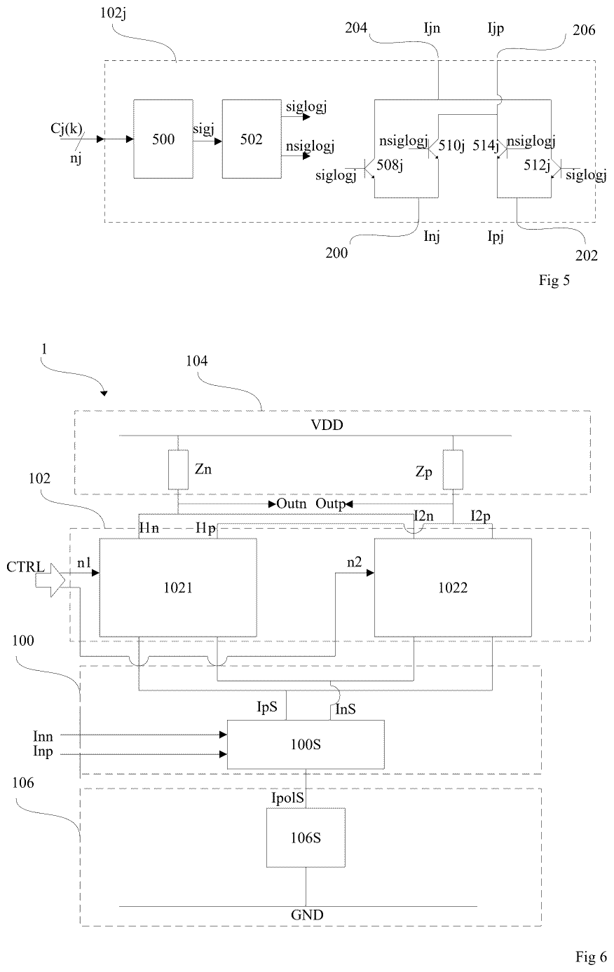

As compared with FIG. 1, in FIG. 7, transconductance gain stage 100 is implemented by a single circuit 106j such as described in relation with FIG. 3, this circuit being designated with reference 106S in FIG. 6.

As a result, biasing stage 106 also comprises a single current source, designated with reference 100S in FIG. 7, supplying a bias current IpolS to stage 100, and more particularly, to circuit 106S.

Stage 100, that is, circuit 100S, delivers two currents InS and IpS corresponding to the products of the transconductance gm of circuit 100S by the respective components Inn and Inp.

These currents InS and Ips are distributed to the parts 102j of stage 102, or, in other words, are distributed between the parts 102j of stage 102.

According to an embodiment, a controllable phase shifter is provided, comprising at least one variable-gain amplifier 1, for example two variable-gain amplifiers 1.

FIG. 7 shows an example of embodiment of a phase shifter 7 comprising at least one variable-gain amplifier 1, and, more particularly, two amplifiers 1.

Device 7 comprises a first amplifier 1 (at the top in FIG. 7) configured to apply a first gain G1 to a first signal sig1. The signal resulting from this amplification is an output signal sig1-G1 of the first amplifier 1.

Device 7 comprises a second amplifier 1 (at the bottom in FIG. 7) configured to apply a second gain G2 to a second signal sigQ in quadrature with signal sig1. The signal resulting from this amplification is an output signal sigQ-G2 of the second amplifier 1.

By recombining the two signals sig1-G1 and sigQ-G2, for example by adding the two signals sig1-G1 and sigQ-G2 to each other, one obtains a signal having a value of the phase shift with signal sig1 which is determined by the values of the gains G1 and G2 applied to the respective signals sig1 and sigQ by the two amplifiers 1.

As an example, the two signals sig1 and sigQ are supplied by an I/Q modulator 700. For example, circuit 700 receives a signal sig1, and supplies signal sig1 in phase with signal sig1, and signal sigQ in quadrature with signal sig1.

According to an embodiment, a device for emitting a shaped beam, or a device for receiving a shaped beam comprising a plurality of phase shifters, each comprising at least one variable-gain amplifier 1, is provided, for example a device for emitting or receiving a shaped beam comprising a plurality of phase shifters 7.

FIG. 8 shows an example of an embodiment of a circuit 8 emitting a shaped beam.

The circuit or device 8 comprises a digital processing circuit NUM configured to receive data to be transmitted data1. Circuit NUM is configured to shape, for example, to encode, data data1, and to deliver a signal data1′ corresponding to a radio frequency transmission chain 802.

The RF transmission chain is configured to deliver, from signal data1′, a plurality of signals data1″ to each of which a different phase shift will be applied. For example, in FIG. 8, RF transmission chain 802 delivers two signals data1″.

Each signal data1″ is supplied to a corresponding phase shifter 7, each phase shifter 7 supplying a signal data1′″ to an antenna 804. More particularly, each phase shifter 7 supplies a signal data′″ corresponding to the signal data1″ received by this phase shifter 7 to which a phase shift of a value controlled, for example, by circuit NUM, has been applied.

The transmission by antennas 804 of the plurality of signals data1″ results in the emission of a corresponding shaped beam beam1.

The path from the reception of data data1 by circuit NUM to the shaped beam beam1 corresponds to a first transmission channel Ch1.

As an example, as shown in FIG. 8, device 8 may comprise more than one channel. For example, in FIG. 8, device 8 comprises a second channel Ch2 comprising the reception of data to be transmitted data2 by circuit NUM, the supply of corresponding data2′ to a radio frequency transmission chain 802, the supply of a plurality of corresponding signals data2″ by this circuit 802 to corresponding phase shifters 7, which each supply a corresponding antenna 804 with a signal data2′″. The transmission by antennas 804 of signals data2′″ with different phase shifts results in the emission of a shaped beam beam2.

FIG. 9 shows an example of an embodiment of a circuit 9 for receiving a shaped beam.

A shaped beam beamA is received by a plurality of antennas 904, for example 2 antennas, of device 9, each antenna delivering a corresponding analog signal dataA.

Each signal dataA is supplied to a corresponding phase shifter 7, which applies a phase shift having a value controlled, for example, by a digital control circuit NUM. Each circuit 7 outputs a signal dataA′ corresponding to the signal dataA that it has received, to which a phase shift of controlled value has been applied.

The analog signals dataA′ are supplied to a radio frequency receiver chain 902, which delivers, from the received signals dataA′, a digital signal dataA″.

Signal dataA″ is supplied to a digital processing circuit NUM. Circuit NUM is configured to decode signals dataA″ so as to extract data dataA′″ which have been transmitted to device 9 via the shaped beam beamA.

The path from the reception of shaped beam beamA by antennas 904 to the received digital data dataA″ corresponds to a first reception channel ChA.

As an example, as shown in FIG. 9, device 9 may comprise more than one channel. For example, in FIG. 9, device 9 comprises a second reception channel ChB comprising the reception, by antennas 904, of a shaped beam beamB, the supply, by these antennas 904, of corresponding analog signals dataB to corresponding phase shifters 7, which each supply a signal dataB′ phase-shifted by a controllable value with respect to the received signal dataB, the supply of analog signals dataB″ to a radio frequency receiver chain 902 which then supplies a digital signal dataB″ from these signals dataB′, and finally the extraction, from signal dataB″ and by circuit NUM, of the received data dataB′″.

Various embodiments and variants have been described. Those skilled in the art will understand that certain features of these various embodiments and variants may be combined, and other variants will occur to those skilled in the art. In particular, although examples where M is equal to 2 have been described, those skilled in the art will be capable to generalizing these examples to cases where M is greater than 2. For example, for M equal to 3, those skilled in the art will be capable of implementing a segmentation of the part 1022 controlled by a control signal over n2 bits into two new parts, one of which is controlled by n21 most significant bits of the n2 bits, and the other by n22 least significant bits of the n2 bits, with n2=n21+n22.

Finally, the practical implementation of the described embodiments and variants is within the abilities of those skilled in the art based on the functional indications given hereabove.

What is claimed is:

1. A variable gain amplification device comprising:
a current switching segmented into at least two parts.

2. The device according to claim 1, wherein the device comprises:
a transconductance gain segmented into at least two second parts.

3. The device according to claim 1, wherein:
the device comprises a Gilbert cell;
the Gilbert cell comprises a transconductance stage, a current switching stage, and a load stage;
the current switching stage is connected between the transconductance stage and the load stage; and
the current switching segmented into the at least two parts is implemented in the current switching stage.

4. The device according to claim 1, wherein:
the device is configured to receive a control signal over N bits, with N a positive integer greater than or equal to 4;
a first one of the at least two parts of the current switching segmentation is configured to be controlled by n1 bits of the control signal; and
a second one of the at least two parts of the current switching segmentation is configured to be controlled by n2 bits of the control signal, with n1 and n2 non-zero positive integers and N=n1+n2.

5. The device according to claim 1, wherein the current switching is at least partly implemented by bipolar transistors.

6. The device according to claim 2, wherein:
the device comprises a Gilbert cell;
the Gilbert cell comprises a transconductance stage, a current switching stage, and a load stage;
the current switching stage is connected between the transconductance stage and the load stage;
the current switching segmented into the at least two parts is implemented in the current switching stage; and
the transconductance gain segmented into the at least two second parts is implemented in the transconductance stage.

7. The device according to claim 2, wherein:
the device is configured to receive an N-bit control signal, with N a positive integer greater than or equal to 4;
a first one of the at least two parts of the current switching segmentation is configured to be controlled by n1 bits of the N-bit control signal;
a second one of the at least two parts of the current switching segmentation is configured to be controlled by n2 bits of the N-bit control signal;
with n1 and n2 non-zero positive integers and N=n1+n2;
a first one of the at least two second parts of the transconductance gain segmentation is configured to implement a first transconductance gain equal to gm1; and
a second one of the at least two second parts of the transconductance gain segmentation is configured to implement a second transconductance gain equal to gm1/(2^{N-n2}).

8. The device according to claim 2, wherein the current switching and the transconductance gain are at least partly implemented by bipolar transistors.

9. The device according to claim 1, wherein at least one of the at least two parts of the current switching segmentation is implemented continuously.

10. The device according to claim 9, wherein the at least one of the at least two parts of the continuously-implemented current switching segmentation comprises a digital-to-analog converter.

11. The device according to claim 1, wherein at least one of the at least two parts of the current switching segmentation is implemented discretely.

12. A phase shifting device comprising:
a first device comprising a first current switching segmented into at least two first parts, the first device configured to apply a first gain to a first signal;
a second device comprising a second current switching segmented into at least two second parts, the second device configured to apply a second gain to a second signal in quadrature with the first signal, the first and second gains determining a phase-shift value; and
an in-phase/quadrature-phase (I/Q) modulator configured to provide the first and second signals.

13. A beam-shaping device configured to emit or receive a shaped beam, the beam-shaping device comprising more than one of the phase shifting device according to claim 12.

14. A variable gain amplification method comprising:
segmenting a current switching in a variable-gain amplification device into at least two parts.

15. The method according to claim 14, further comprising:
segmenting a transconductance gain into at least two second parts.

16. The method according to claim 15, wherein the device comprises a Gilbert cell having a transconductance stage, a current switching stage, and a load stage, with the current switching stage being connected between the transconductance stage and the load stage, and the method further comprises:
implementing the segmenting of the current switching into the at least two parts in the current switching stage; and
implementing the segmenting of the transconductance gain into the at least two second parts in the transconductance stage.

17. The method according to claim 14, wherein the device comprises a Gilbert cell having a transconductance stage, a current switching stage, and a load stage, with the current switching stage being connected between the transconductance stage and the load stage, and the method further comprises:
implementing the segmenting of the current switching into the at least two parts in the current switching stage.

18. The method according to claim 14, further comprising:
receiving, by the device, a control signal over N bits, with N a positive integer greater than or equal to 4;
controlling a first one of the at least two parts of the segmented current switching by n1 bits of the control signal; and
controlling a second one of the at least two parts of the segmented current switching by n2 bits of the control signal, with n1 and n2 non-zero positive integers and N=n1+n2.

19. The method according to claim 14, further comprising implementing the current switching at least partly by bipolar transistors.

20. The method according to claim 14, further comprising implementing at least one of the at least two parts of the segmented current switching continuously or discretely.
